(19) United States
(12) Patent Application Publication
(10) Pub. No.: US 2010/0199146 A1
(43) Pub. Date: Aug. 5, 2010

(54) STORAGE SYSTEM, STORAGE CONTROLLER AND METHOD FOR CONTROLLING STORAGE SYSTEM

(75) Inventors: Yuichi Sato, Kawasaki (JP); Hiroaki Kameyama, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/755,581

(22) Filed: Apr. 7, 2010

Related U.S. Application Data
(63) Continuation of application No. PCT/JP2007/001114, filed on Oct. 15, 2007.

(51) Int. Cl. G11C 29/42; G06F 12/00; H03M 13/00; G06F 11/00

(52) U.S. Cl. 714/758; 711/114; 714/770; 714/E11.02

(57) ABSTRACT

In a storage controller provided for a storage system provided with a plurality of disk devices, for controlling to storage data in the plurality of disk devices, an encoding unit encodes data to be stored in the plurality of disk devices by erasure correction coding to obtain encoded data. A storage/reading unit stores the encoded data in the plurality of disk devices and fetches the encoded data from the plurality of disk devices, according to instructions from a personal computer. A transmitting unit transmits the encoded data fetched from the plurality of disk devices by the storage/reading unit to a storage system 1B connected to a storage system 1A via a network.

### CROSS REFERENCE TO RELATED APPLICATION

This application is a continuation of PCT application PCT/JP2007/001114, which was filed on Oct. 15, 2007.

### FIELD

The embodiments discussed herein are related to a storage system for distributing/storing data to/in a plurality of disk devices.

### BACKGROUND

Recently, in a storage system, an array-structured disk array device for encoding data by using Reed-Solomon coding (RS coding) or the like to maintain the reliability of data when storing data and also distributing/storing data to/in a plurality of magnetic disk drives has been often used. Furthermore, the disk array devices are geographically distributed and an anti-disaster system is also constructed in order to protect data from disasters, such as an earthquake, a fire and the like by connecting between the devices via a communication line, such as Ethernet (trade mark) or the like and copying data (mirroring) or the like.

Conventionally, when data is stored in the storage system other encoding/decoding methods different from those used when data is transferred between networks in mirroring or the like are adopted. Specifically, when data is transferred to a storage system connected to it via a network, firstly encoded data is read from a disk drive and is decoded. Then, the data is transmitted after being encoded again by the encoding method at the time of data transfer.

In this case, as to the transmission/reception of data between storage systems, time delay proportional to a transmission distance occurs in data transfer. When a line is congested, data transfer takes a longer time. Conventionally, since data is transferred by a transmission control protocol (TCP), when data transfer takes a longer time, the response time of a data transfer command delays and as a result, sometimes a time-out error occurs.

In order to solve such a problem, a method for monitoring the response time of data transmitting/receiving commands between devices and adjusting/setting the issuance times of a command within a certain time and a command response transmitting data transfer length, on the basis of the response time is proposed (for example, Japanese Laid-open Patent Publication No. 2002-196894).

A method for preventing congestion and over-suppression from occurring to prevent the decrease of a transfer efficiency by adjusting the total amount of transferred data at one time according to the delay time of data transfer is also proposed (for example, Japanese Laid-open Patent Publication No. 2003-256149).

Besides these, a method for preparing the same number of network lines as the number of disk arrays constituting a storage system device and omitting the decoding process of original data by transmitting data for each corresponding disk array is also proposed (for example, Japanese Laid-open Patent Publication No. 2004-185416).

### SUMMARY

According to an aspect of an embodiment of the invention, a storage controller controls storing data in a plurality of disk devices in a storage system provided with the plurality of disk devices, and the controller includes an encoding unit for encoding data to be stored in the plurality of disk devices by erasure correction coding to obtain encoded data; a storage unit for storing the encoded data in the plurality of disk devices and fetching the encoded data from the plurality of disk devices according to instructions from a host computer; and a transmitting unit for transmitting the encoded data fetched from the plurality of disk devices by the storage unit to another storage system connected to the storage system via a network.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a configuration of a storage system.

FIG. 2 is a block diagram of a RAID controller.

FIG. 3 explains the transmission/reception of a dummy response message.

FIG. 4 explains how to measure a loss factor.

FIG. 5 illustrates the relationship between transfer speed and a packet loss factor for each transfer method of data.

FIGS. 6A-6B are a configuration of a disk array device.

FIG. 7 is a graph illustrating various comparison results of a conventional writing process of encoded data and a writing process of encoded data by RPS coding.

FIG. 8 explains an encoding matrix of RSP coding.

FIG. 9 is one example of an RSP encoding table.

FIG. 10 explains how to generate parity data.

FIG. 11 is a flowchart illustrating a data transfer process of a storage system on a data transmitting side.

FIG. 12 is a flowchart illustrating a data receiving process of a storage system on a data receiving side.

FIG. 13 compares the relationship between a packet loss factor and transfer speed of a data transfer method according to the preferred embodiment with the relationship between a conventional packet loss factor and conventional transfer speed.

FIG. 14 compares the relationship between a delay time due to a transfer distance and transfer speed of a data transfer method according to the preferred embodiment with the relationship between a conventional delay time due to a transfer distance and conventional transfer speed.

### DESCRIPTION OF EMBODIMENTS

According to the methods of the above-described Patent documents (i.e., Japanese Laid-open Patent Publication No. 2002-196894 and Japanese Laid-open Patent Publication No. 2003-256149), when data is transferred to a remote storage system, a data transfer source transfers data after once decoding encoded data in a storage system. Then, a data transfer destination encodes the data, re-distributes the data to a storage system and so on after confirming that the data could be surely decoded. Therefore, the overhead of the entire system increases, which is a problem.

According to a method of the above-described Japanese Laid-open Patent Publication No. 2004-185416, it is necessary to prepare another line for each disk array and it cannot be said that its practicability is high. As to a data loss, such as a packet loss caused during data transfer via a network and the like, since data is compensated on a network device side, its overhead at the time of data loss occurrence becomes large, which is a problem.

Preferred embodiments of the present invention will be explained below in detail with reference to accompanying drawings.

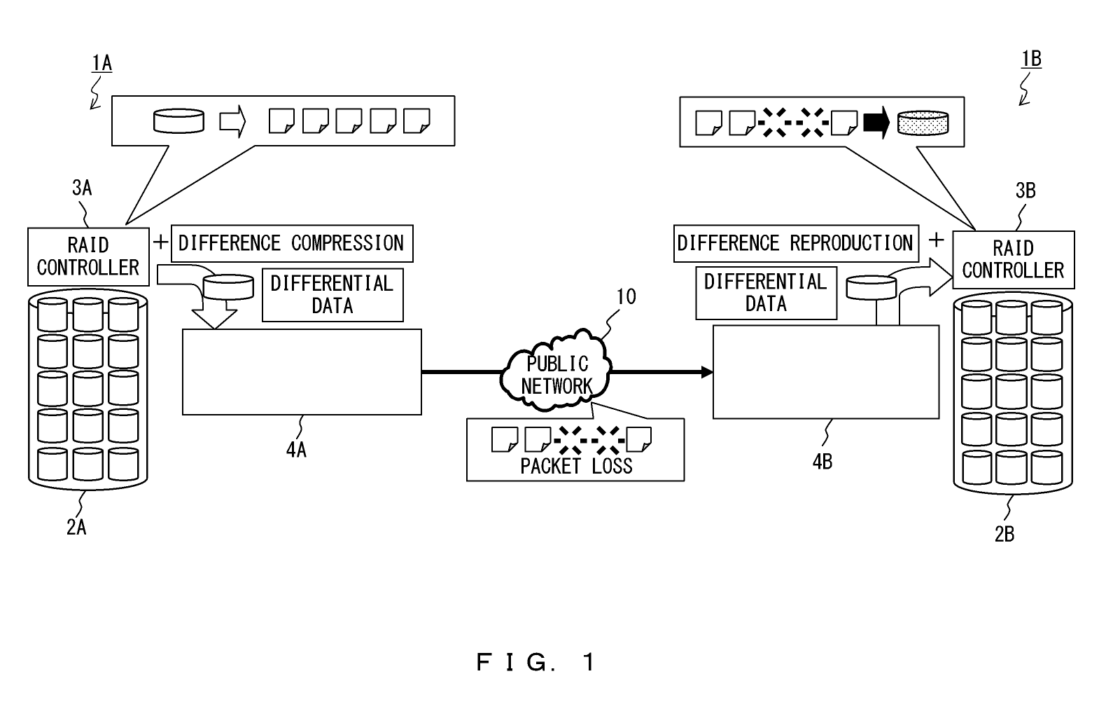

FIG. 1 is the configuration of a storage system according to this preferred embodiment. In FIG. 1, two storage systems 1 are connected via a network 10, such as a public network or the like. Of the two storage systems, one on the data transmitting side and the other on the receiving side are expressed as storage systems 1A and 1B, respectively. When the transmitting and receiving sides of data are separately expressed in the following explanation and drawings, symbols “A” and “B” are attached to devices on the transmitting and receiving sides, respectively. When no such distinction is necessary, the symbols are omitted.

Each storage system includes a disk array device 2, a RAID (redundant arrays of inexpensive (or independent) disks) controller 3 and a transmitting/receiving device 4. Although in this case the storage system 1 has a RAID6 configuration, it can also have a RAID5 or less configuration.

The disk array device 2 includes a plurality of disks. The RAID controller 3 controls to store/fetch data in/from a disk device provided for the disk array device 2 and the like according to an instruction from a host computer, which is not illustrated in FIG. 1. The transmitting/receiving device 4 includes a transfer device, such as a network adapter or the like and transfers data fetched from the disk array device 2 to another storage system 1.

According to the storage system 1 according to this preferred embodiment illustrated in FIG. 1, the same encoding method is adopted for both storing data in the disk array device 2 and transferring data to another storage system 1 in a mirroring process. If a storage system 1A on the transmitting side recognizes that the loss of a data packet occurs on the network 10 when data is transferred to another storage system 1, it reads encoded data from the disk device of the disk array device 2 according to the loss factor of a packet and directly transmits the read data.

The transmitting/receiving device 4 performs various publicly known processes, such as band control, IPSec (security architecture for Internet protocol) encipherment, LFT (long fat tunnel) protocol conversion and the like to make a packet of data transferred from the RAID controller 3 and transmit it. When receiving the data packet transferred from the network 10, the device 4 fetches the data and gives it to the RAID controller 3.

For an encoding method to be adopted, an encoding method disclosed by Japanese Laid-open Patent Publication No. 2006-271006, a Reed Solomon coding, Cauchy Reed-Solomon coding or the like is used.

In the following description, the above-described encoding method disclosed by Japanese Laid-open Patent Publication No. 2006-271006 is called as RPS (random parity stream) coding. A method for storing data encoded by the RPS coding in a disk device and a method for transferring the data to another storage system will be described later.

An encoding process by the RPS coding is performed by the RAID controller 3.

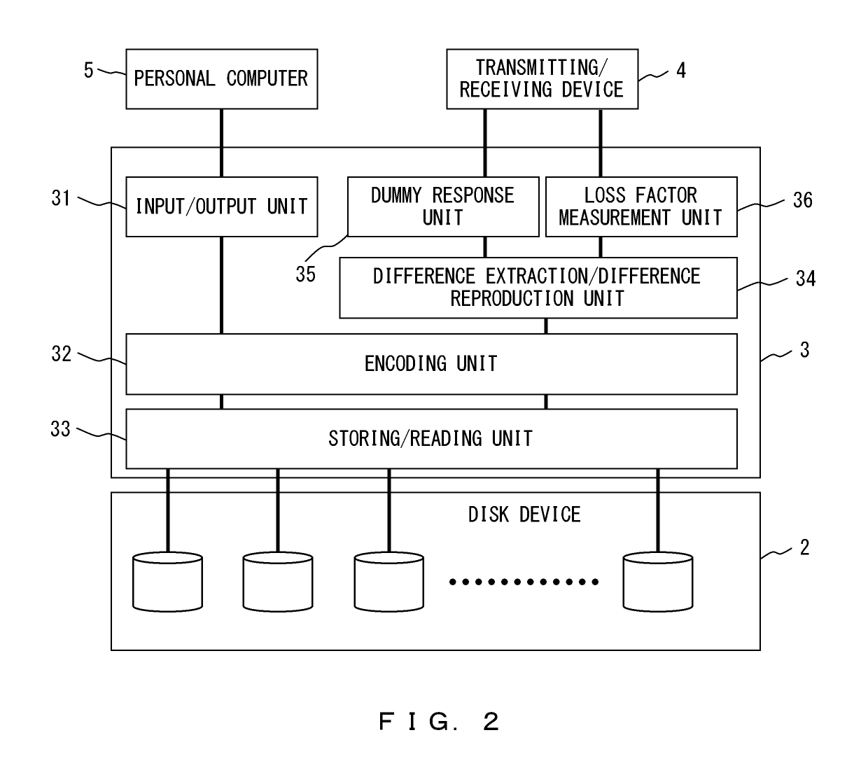

Next, the configuration of a RAID controller is explained with reference to FIG. 2. FIG. 2 is the block diagram of the RAID controller 3. FIG. 2 illustrates a block diagram common to the RAID controllers 3A and 3B on the receiving and transmitting sides, respectively.

The RAID controller 3 is connected to the disk array device 2, a personal computer 5 and the transmitting/receiving device 4. The RAID controller 3 includes an input/output unit 31, an encoding unit 32, a storage/reading unit 33, a difference extraction/decoding unit 34, a dummy response unit 35 and a loss-factor measurement unit 36.

The input/output unit 31 receives instructions from the personal computer 5 being a host computer and inputs/outputs data.

The encoding unit 32 encodes data to be stored in the disk device of the disk array device and data to be additionally transmitted to the other storage system 1B, according to instructions from the input/output unit 31.

The storage/reading unit 33 writes data encoded by the encoding unit 32 to and reads data from a disk device.

When data is transmitted to another storage system 1, the difference extraction/decoding unit 34 extracts the difference between previously transmitted data and data to be transmitted. When data is received from another storage system 1, the difference extraction/decoding unit 34 performs a decoding process on the basis of the difference between previously transmitted data and data to be transmitted.

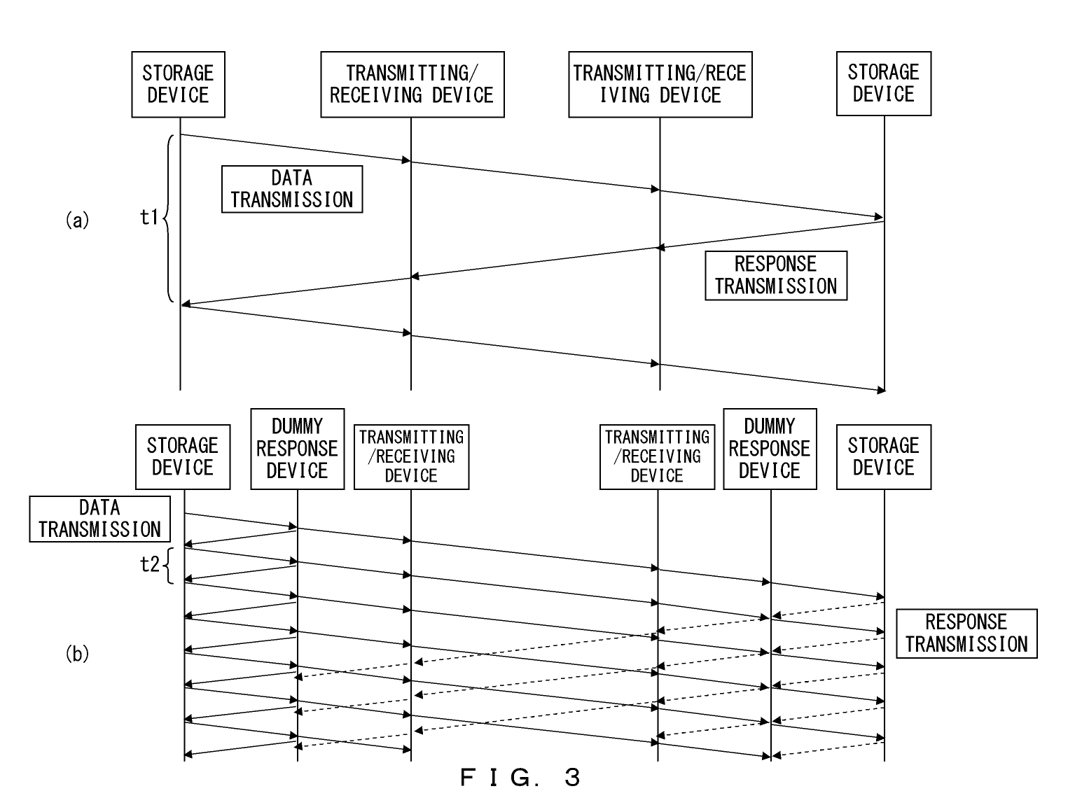

The dummy response unit 35 receives the dummy response message of the data after transferring data to be transmitted to the storage system 1B, to the transmitting/receiving unit 4. In this case, “the dummy response message” is a message corresponding to an “actual response message” transmitted from the storage system 1B side being a data receiving device, specifically a message used to recognize that the RAID controller 3A receives a response. The dummy response message is transmitted from the transmitting/receiving device 4A for transmitting data to the network 10. The transmission/reception of the dummy response message will be described in detail later with reference to FIG. 3.

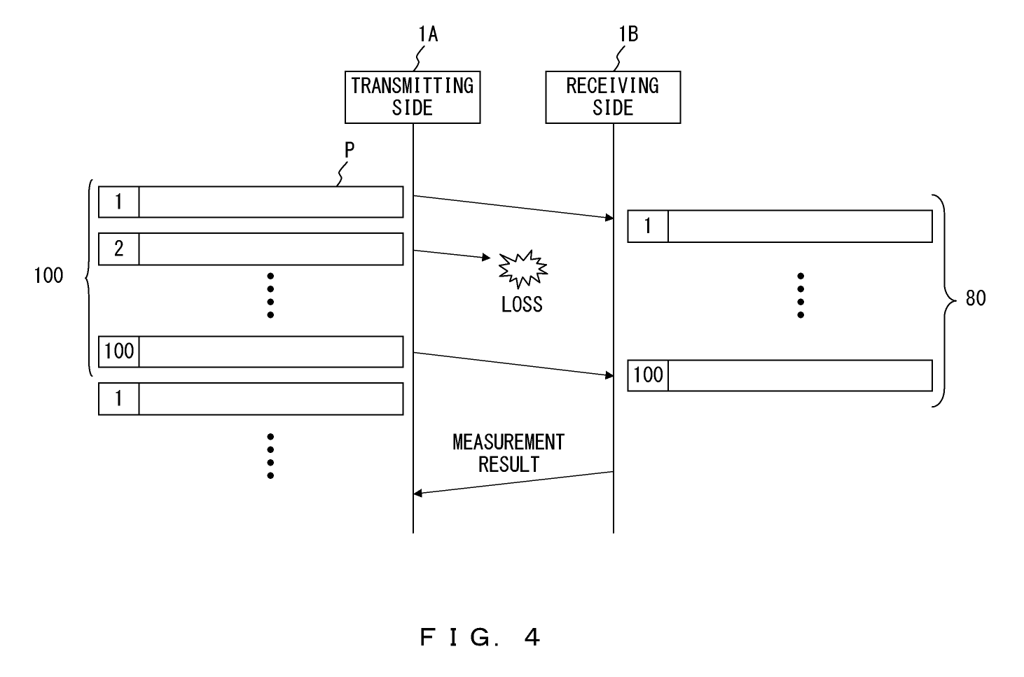

The loss-factor measurement unit 36 measures a packet loss factor on the network 10 by counting the number of received packets in the storage system 1B for receiving data by mirroring or the like. The detailed method of loss-factor measurement will be described in detail later with reference to FIG. 4.

FIG. 3 explains the transmission/reception of a dummy response message. FIG. 3A is the sequence of a conventional data transfer process. FIG. 3B is the sequence of a data transfer process according to this preferred embodiment.

As illustrated in FIG. 3A, conventionally when fetching data a storage device, the RAID controller 3A on the transmitting side transmits a data packet via the transmitting/receiving device 4A. When recognizing that the data packet is received via the transmitting/receiving device 4B, the RAID controller 3B on the receiving side stores the data in a storage device and also transmits a response message toward the transmitting side. Upon receipt of the response message, the RAID controller 3A reads and transmits data to be subsequently transmitted.

However, as illustrated in FIG. 3B, when data is read from a storage device and is transmitted in this preferred embodiment, a dummy response device provided on the transmitting side returns a dummy response message. Upon receipt of the dummy response message, subsequent data is read and transmitted.

Although an actual response message is transmitted from the storage system 1B on the receiving side, in this preferred embodiment, subsequent data is transmitted on the basis of the fact that a dummy response transmitted to the RAID controller 3A from the transmitting/receiving device 4A is received. By transmitting data according to a dummy response message, a time for waiting for a response message from the receiving side is shortened.

Conventionally, since data is transmitted by a TCP, the longer is the distance between the storage systems 1, the more time required for data transfer, thereby making a waiting time t1 until a response message is received longer. However, according to the data transfer method of this preferred embodiment, there is no need to wait for a response message transmitted to the transmitting side from the receiving side of data, thereby sequentially transmitting data to be transferred. Specifically, a time t2 until subsequent data is transmitted can be made shorter than the above-described waiting time t1. Thus, data transfer efficiency can be improved.

FIG. 4 explains how to measure a loss factor according to this preferred embodiment. On the transmitting side a serial number is attached to each data packet P to be transferred. On the receiving side the number of data packets that reached the storage system 1B on the receiving side is counted. Then, the ratio of data packets that arrived to the number of transmitted data packets is calculated for every specific number of data packets as a packet loss factor. The receiving side recognizes the specific number of data packets with reference to the serial number attached to each data packet. Specifically, if a serial number is attached from 1 when a loss factor is measured, for example, every 100 data packets, the loss factor is measured with timing the 100-th data packet is received. If the 100-th data packet does not reach the receiving side due to a packet loss, a loss factor is measured when a serial number after 100, that is, a data packet with a serial number 101 or after is recognized.

As illustrated in FIG. 4, it is assumed that of 100 data packets transmitted to the network 10, for example, 80 data packets are received on the receiving side. In this example, a loss factor is calculated as 100−(80/100)×100=20%.

The storage system 1B transmits the measured loss factor to the storage system 1A. The storage system 1A being a data transmitting source analyzes the received information and reflects the measurement result of the loss factor in the storage system 1B in data transfer. Specifically, the storage system 1A determines the amount of data to additionally transmit according to the received packet loss factor.

In this example, the packet loss factor is measured every 100 data packets and the calculated loss factor is regularly transmitted to the storage system 1A on the transmitting side. The storage system 1A being a data transmitting source additionally transmits the parity data of data included in these data packets according to the loss factor of 100 data packets from serial numbers n (n=integer) through n+99.

According to the data transfer method according to this preferred embodiment, even when a packet loss is detected, data is not re-transmitted. Instead of re-transmitting data, its parity data stored in a parity disk of the RAID is transmitted.

When parity data is dynamically generated and is additionally transmitted, a difference compression technology can also be adopted to suppress the amount of data to additionally transmit to a low level.

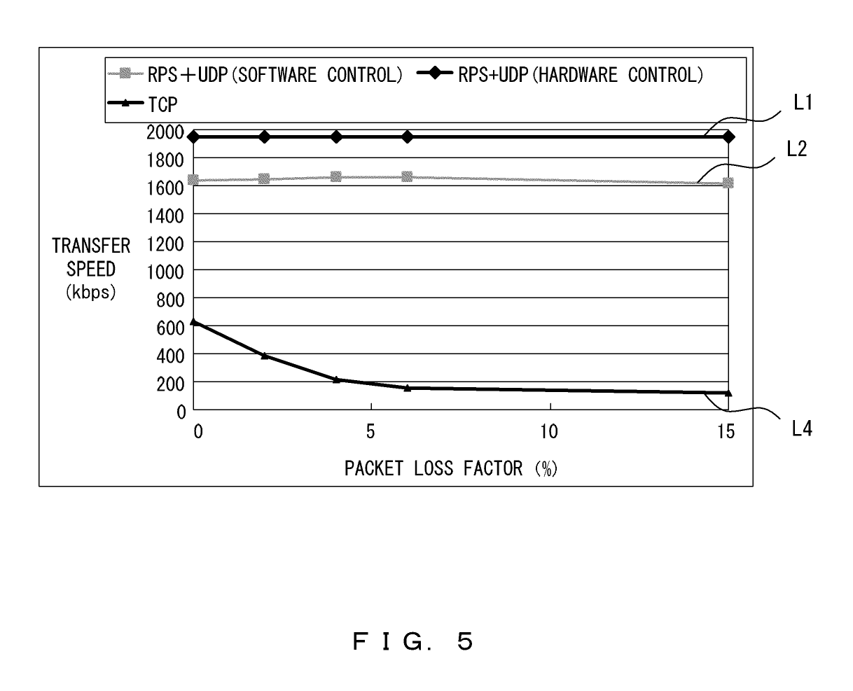

FIG. 5 illustrates the relationship between transfer speed and a packet loss factor for each transfer method of data. In this example, the change of data transfer speed due to a packet loss factor in the case where data is transferred with a band of 2 Mbps and a round trip time (RTT) of 400 ms using a public network is illustrated for each data transfer method.

Of four graphs illustrated in FIG. 5, L1 and L2 are graphs in the case where data encoded by RPS coding is transferred by a data transfer method according to this preferred embodiment. L4 is a graph in the case where encoded data is transferred by the conventional TCP.

As illustrated in FIG. 5, according to a data transfer method by the conventional TCP, when a packet loss is recognized, data is re-transmitted. The higher a packet loss factor, the larger the amount of data to re-transmit. Therefore, there is a tendency for transfer speed to decrease as a packet loss factor increases.

However, according to a data transfer method in this preferred embodiment, the storage system 1A continues to sequentially transmit data packets without waiting for a response message from the storage system 1B on the receiving side. Then, additional parity data is generated according to a packet loss factor, and its packet is made and transmitted. Since there is no need to re-transmit data, even when the packet loss factor increases, transfer speed does not decrease.

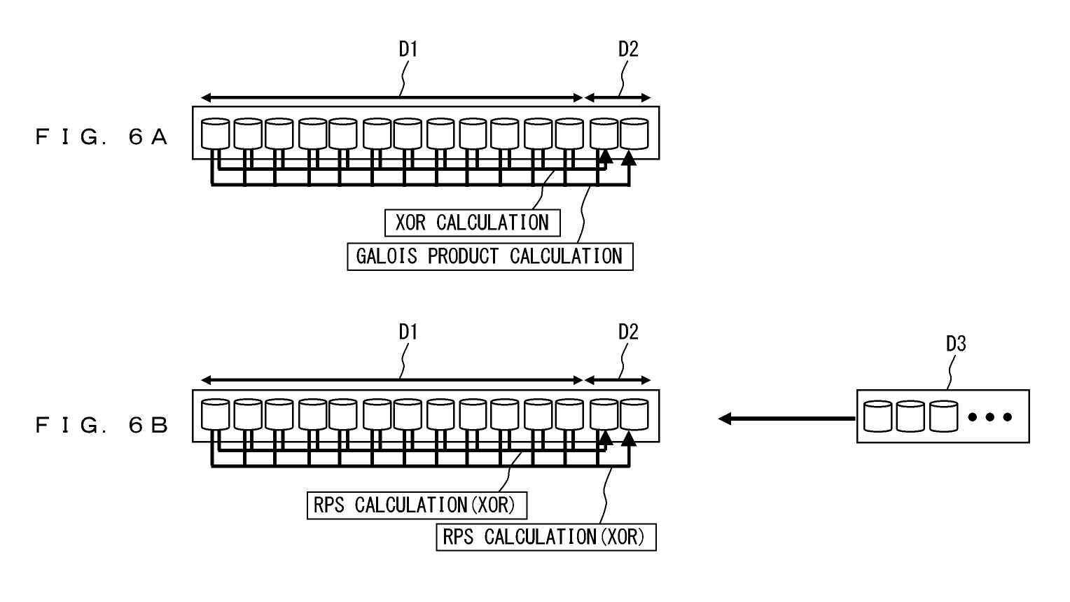

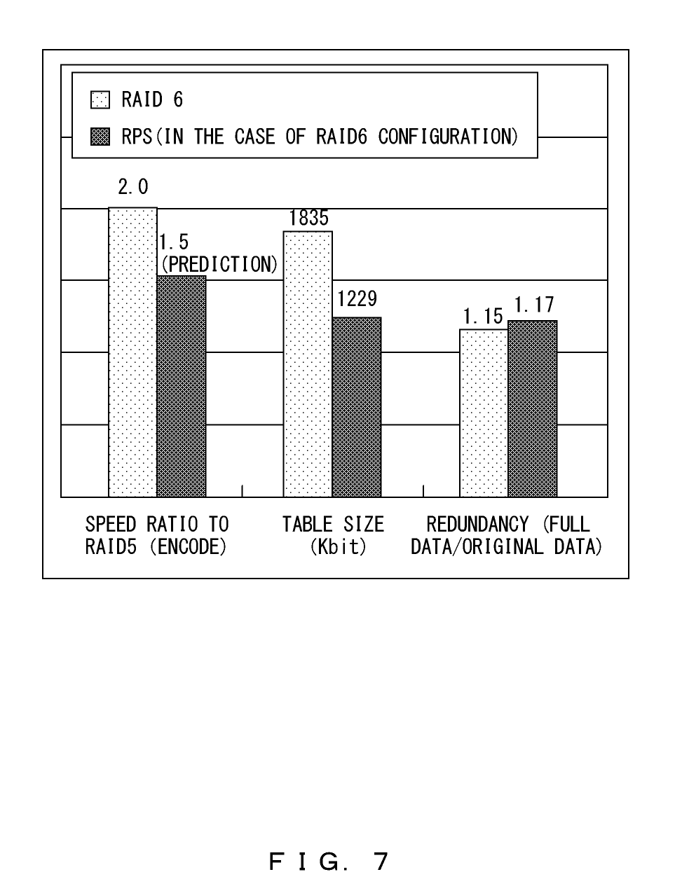

As described above, in the storage system 1 according to this preferred embodiment, the same correction coding method is adopted for both transferring data and storing data in a disk device. Next, a method for storing data in a disk device using RPS coding will be explained with reference to FIGS. 6A, 6B and 7.

FIGS. 6A and 6B are the configuration of a disk array device. FIG. 6A illustrates the configuration of a conventional disk array device and FIG. 6B illustrates the configuration of the disk array device 2 according to this preferred embodiment.

As illustrated in FIG. 6A, in the conventional RAID6 configuration, of a plurality of disk devices (14 disk devices in the example illustrated in FIG. 6A), two are parity disks D2 and the remaining 12 are data disks D1. When data is written by a (P+Q) method, parity obtained by Galois product calculation and parity obtained by XOR calculation are stored in one and the other, respectively, of the two parity disks 2. In such a configuration, data can be compensated for the failure of two disk devices.

However, as illustrated in FIG. 6B, in this preferred embodiment, data encoded by RPS coding is written in a disk device. In RPS coding, only XOR calculation is performed. In the configuration of FIG. 6B, of a plurality of disk devices, two are parity disks D2 and the remainder is data disks D1. According to the RPS coding, besides an additional parity disk D3 can also be prepared to provide three or more parity disks (described in detail later). Thus, data can be compensated for the failure of three or more disk devices.

FIG. 7 is a graph illustrating various comparison results between the case where data is encoded by a conventional (P+Q) method and is written and the case where data is encoded by RPS coding and is written. In both cases, a RAID6 configuration is adopted. Comparison of writing speed into a disk device with RAID5, a table size sufficient for storing an encoding matrix and data redundancy are illustrated sequentially from the left side in FIG. 7.

As to the writing speed, according to an RPS coding method, since no Galois product calculation is required unlike a (P+Q) method, data can be processed in higher speed.

According to RPS coding, the table size can be equal to or smaller than conventional one.

According to RPS coding, data can be encoded with almost the same redundancy as conventional one. The redundancy illustrated in FIG. 7 is defined by the ratio of the amount of data including parity data, written in a disk device (total amount of data) to the amount of data to be stored in a disk device (original amount of data).

In this way, by encoding data stored in the disk device of the disk array device 2 by RPS coding, a memory size needed to store an encoding matrix can be equal to or suppressed at a lower level than conventional one. A writing process can be also performed in high speed while maintaining a redundancy value equal to conventional one.

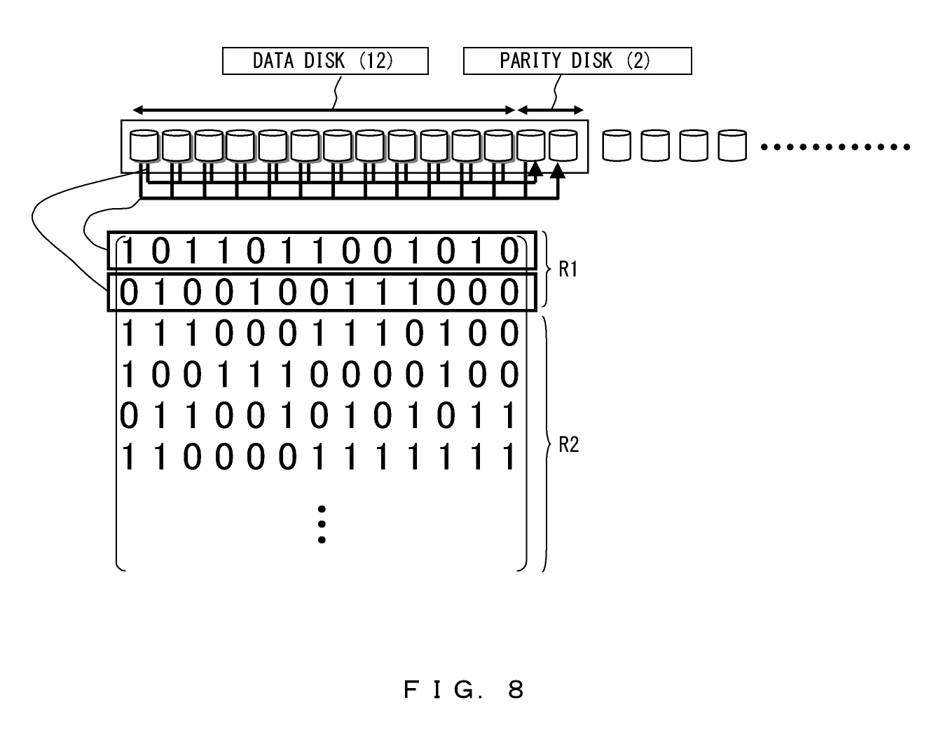

FIG. 8 explains the encoding matrix of RSP coding.

In FIG. 8, in a RAID6 configuration, of 14 disk devices, 12 are disk devices for data and two are disk devices for parity data.

The first and second rows (R1 in FIG. 8) of an encoding matrix are used to calculate parity data to be stored in two respective parity disk devices.

As to the third and after lines (R2 in FIG. 8) of the encoding matrix of RPS coding, respective matrix elements are set so as to tally actual data. Specifically, data encoded using the third and after rows constitutes parity data. Thus, as described above, a parity disk for storing the data encoded using the third and after rows can be added.

Alternatively, when a packet loss is detected, parity data can also be newly generated using the third and after rows and the obtained encoded data can also be additionally transmitted. A storage system that has received the additional data packet stores the same encoding matrix as the transmitting side and reproduces actual data on the basis of the parity data.

Respective matrix elements of the encoding matrix of RPS coding illustrated ion FIG. 8 are stored in memory or the like provided for the RAID controller 2 in advance as an RPS encoding table. When parity data is generated and when reproduction is performed using the parity data, necessary matrix elements are read from the RPS encoding table stored in the memory or the like.

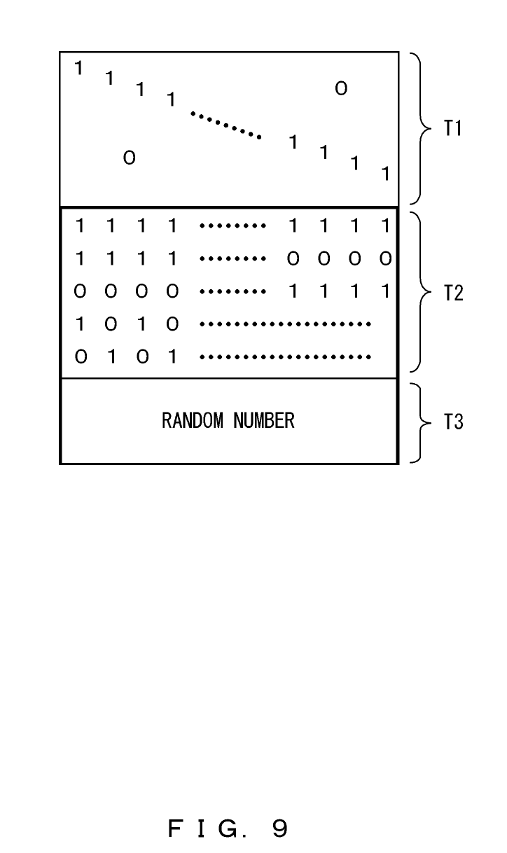

FIG. 9 is one example of the RSP encoding table. The RSP encoding table illustrated in FIG. 9 includes three table portions T1, T2 and T3.

The first table T1 stores the matrix elements of a unit matrix. Data to be transferred is systematically encoded by the matrix element data stored in the first table T1 and is encoded for each disk device.

The second table T2 stores matrix elements for encoding by the RPS coding illustrated in FIG. 8. The combination of respective matrix elements which define which parity data corresponding to data stored in a disk device should be transmitted when any of a plurality of disk devices fails is calculated by simulation or the like. Therefore, data can be more surely reproduced due to the time taken to appropriately calculate matrix elements.

The third table T3 stores the arrangement of matrix elements calculated by random numbers. As illustrated in FIG. 9, a matrix calculated by random numbers can also be stored in a table in advance.

Alternatively, when it becomes necessary to reproduce data due to the failure of a disk device and when it becomes necessary to additionally transmit parity data for the reason a packet loss occurs at the time of data transfer, a matrix can also be generated using random numbers. In this case, the size of the RPS encoding table can be minimized and the amount of used memory can be suppressed to a low level.

Furthermore, either the second table T2 storing matrix elements calculated by simulation or the third table T3 storing matrix elements calculated by random numbers can also be stored.

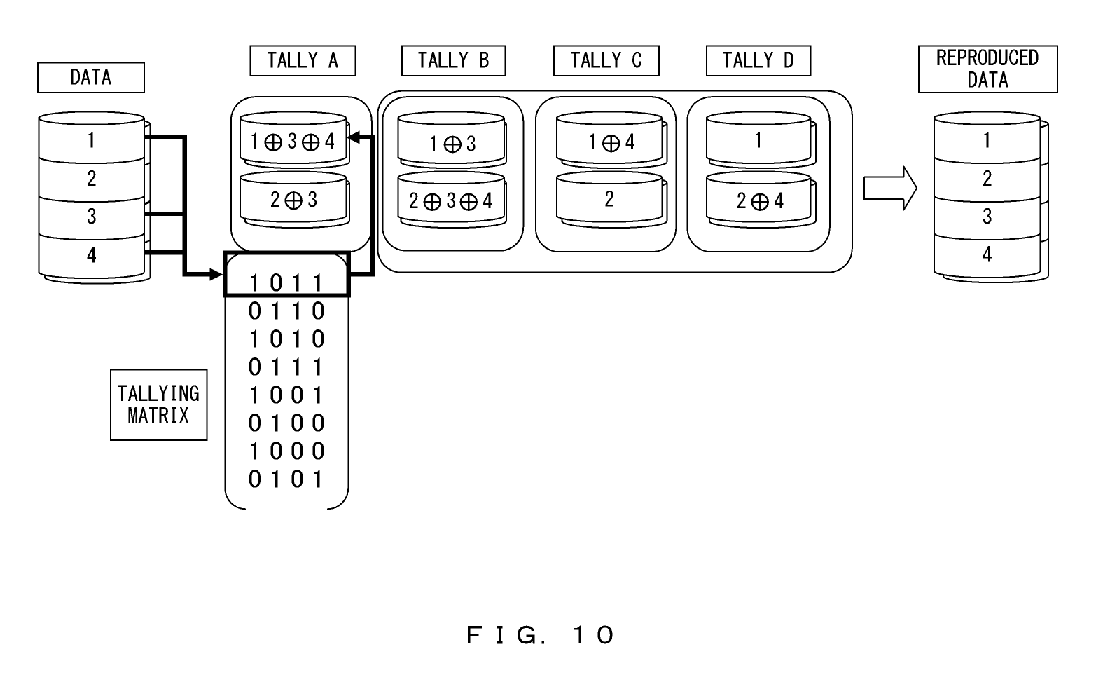

FIG. 10 explains how to generate parity data according to this preferred embodiment. It is assumed that actual data stored in a data disk device is “data 1” through “data 4”. When a disk device fails or when a packet loss occurs on the network 10, as described above, data is reproduced using parity data. The parity data can be obtained by tallying actual data. More specifically, of matrices (encoding matrices) for tally illustrated in FIG. 8, the exclusive OR (hereinafter expressed as “XOR”) between a plurality of pieces of data corresponding to the matrix elements whose values correspond to 1 is calculated to obtain tally data.

In the matrix illustrated in FIG. 10, the first row is composed of (1, 0, 1, 1). In this case, it is assumed that the XOR of data 1, 3 and 4 is tally data. The second row of the matrix is composed of (0, 1, 1, 0) and it is assumed that the XOR of data 2 and 3 is tally data. As to the other rows, tally data is generated by calculation their XOR using the same method.

The amount of data to be used for restoring data lost on the network 10, of the tally data generated by the above-described method is determined according to its packet loss factor. According to the data transfer method of the above-described preferred embodiment, when data is additionally transmitted at the occurrence time of a packet loss, the storage system 1A on the transmitting side cannot recognize which data has not reached the receiving side. However, by transmitting the above-described tally data as additional data, the lost data can be more surely reproduced on the receiving side.

By increasing the number of rows of a matrix to increase the number of generated tally data, a parity disk device can be extended. By increasing the number of parity disk devices, data can be more surely compensated at the failure time of a disk in the storage system 1.

When a packet loss occurs or when a disk fails, by calculating the XOR between a plurality of pieces of tally data, original data can be reproduced.

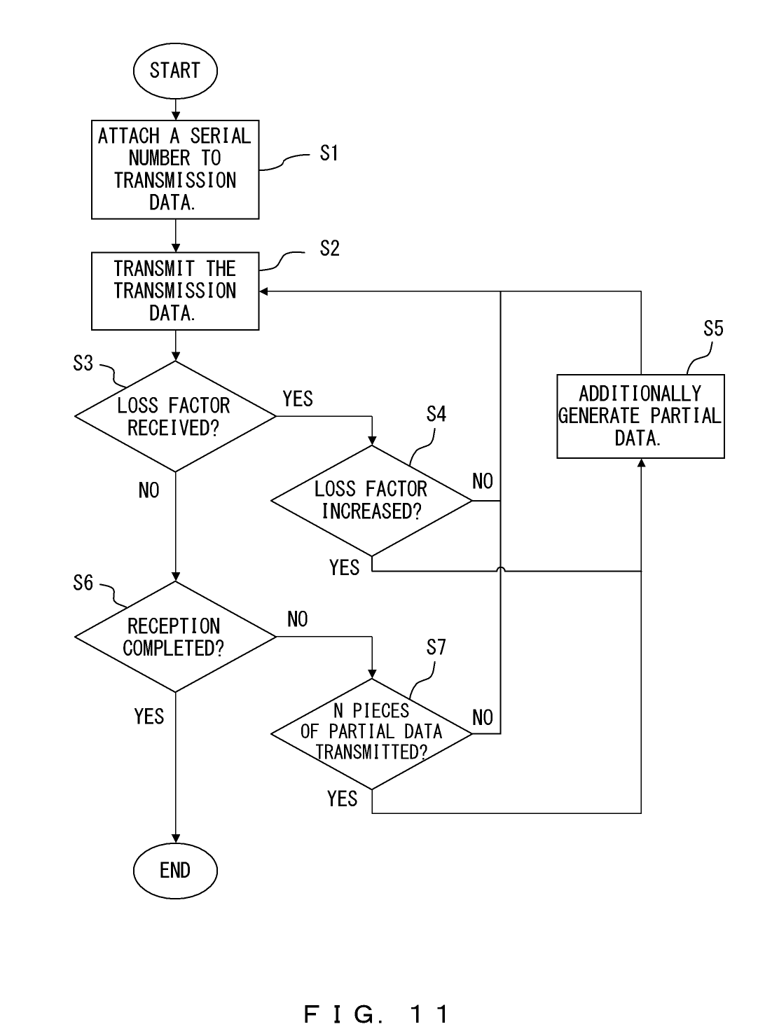

FIG. 11 is a flowchart illustrating the data transfer process of the storage system 1A on the data transmitting side.

Firstly, in step S1 a serial number is given to each data packet of data to be transmitted. In step S2 the data is transmitted. In step S3 it is determined whether a loss factor transmitted from the storage system 1B of a data transmitting destination is received.

If the loss factor is received, the process advances to step S4, where it is determined whether the loss factor is larger than previously received one. If there is no change in the loss factor or if the loss factor is smaller than the previously received one, the process returns to step S2. If the transmission of the data to be transmitted is not completed yet, data is transmitted.

If in step S4 it is determined that the loss factor is larger than the previously received loss factor, the process advances to step S5 and partial data is additionally generated. Then, the process returns to step S2 and the generated parity data is transmitted. In this case, the partial data means parity data for reproducing lost data on the receiving side. The parity data is composed of the tally data generated by the above described encoding matrix and for part of the entire data transmitted in step S2.

If in step S3 it is determined that the loss factor is not received, the process advances to step S6. Then, in step S6 it is further determined whether a data reception completion message transmitted from the storage system 1B is received.

If in step S6 it is determined that the data reception completion message is not received yet, the process advances to step S7 and it is determined whether n pieces of additional partial data (parity data) is already transmitted. If they are not transmitted, the process returns to step S2 and the transmission of data is continued. If it is determined that the n pieces of additional data are already transmitted, the process advances to step S5 and partial data is additionally generated. Then, the parity data generated in step S2 is transmitted.

If in step S6 it is determined that the data reception completion message is received, the data transmitting process is terminated.

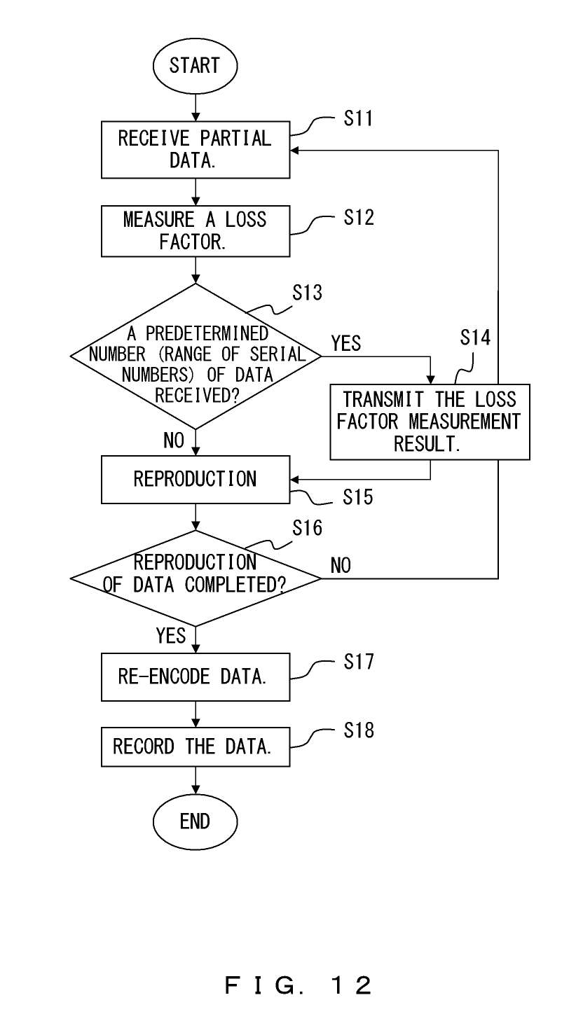

FIG. 12 is a flowchart illustrating the data receiving process of the storage system 1B on the data receiving side.

Firstly, when in step S11 partial data is received, in step S12 a loss factor is measured on the basis of a serial number attached to the received partial data and the number of received packets. Then, in step S13 it is determined whether a predetermined number of data packets are received. In this case, the predetermined number of data packets is a group of data packets whose loss factor is measured. In the example illustrated in FIG. 4, the group includes 100 data packets of the first through the 100-th.

If in step S13 it is determined that the predetermined number of data packets are received, the process advances to step S14. In step S14, a loss factor is calculated by calculating the ratio of the received number of packets to the predetermined number of packets in step S13, the measurement result is transmitted to the storage system 1A on the transmitting side and the process advances to step S15. If in step S13 it is determined that the predetermined number of data packets are not received, it is determined that the received data is parity data and the process advances to step S15 without the measurement of a loss factor.

In step S15 data is reproduced. Then, in step S16 it is determined whether the reproduction of data is completed. If it is determined that the reproduction of data is not completed yet, the process returns to step S11. If it is determined that the reproduction of data is completed, the process advances to step S17.

When in step S17 the data is re-encoded by RPS coding, in step S18 the data is stored in the respective disk devices of the disk array device 2 and the process is terminated.

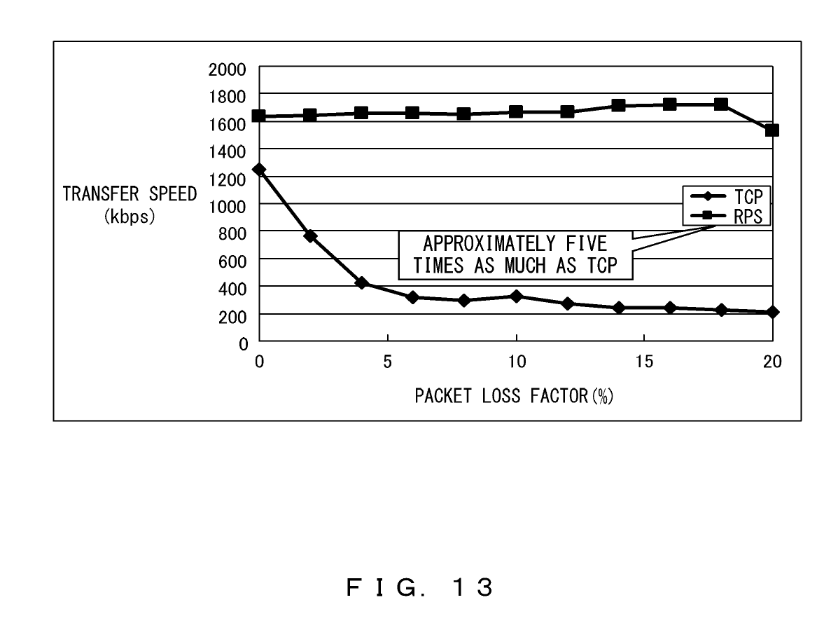

FIG. 13 compares the relationship between a packet loss factor and transfer speed of a data transfer method according to the preferred embodiment with the relationship between a conventional packet loss factor and a conventional transfer speed. In FIG. 13 comparison is performed under the radio communication environmental condition that a band, an RTT and a file size are 2 Mbps, 200 ms and 4 MB, respectively.

According to the conventional data transfer method using a TCP, a data packet whose arrival at a storage system on the receiving side is not recognized is re-transmitted. Therefore, when a packet loss factor increases, the number of data packets to be re-transmitted increases, thereby reducing data transfer speed.

However, according to the data transfer method according to this preferred embodiment, as described above, when a packet loss is detected, the amount of parity data corresponding to the value of a loss factor is additionally transmitted. The additionally transmitted amount of data does not necessarily increase in proportion to the packet loss factor. Thus, transfer speed can be kept almost constant regardless of the value of the packet loss factor.

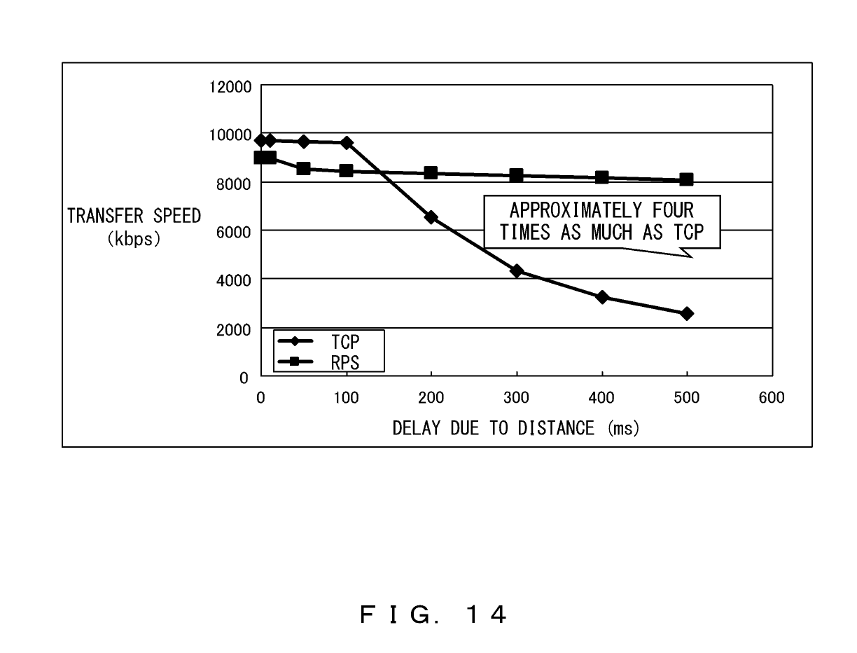

FIG. 14 compares the relationship between a delay time due to a transfer distance and a transfer speed of a data transfer method according to the preferred embodiment with the relationship between a conventional delay time due to a transfer distance and a conventional transfer speed. In FIG. 14, comparison is performed in a wired communication environment by an optical fiber where a band and a file size are 10 Mbps and 200 MB, respectively.

In the wired communication environment, since communication is conducted by a TCP, its response message is awaited every time a data packet is transmitted. When the response message is not received, the data packet is re-transmitted. In this case, the longer is a distance, the more time is required to receive the response message. Therefore, the more is a delay time, the more transfer speed decreases. However, according to the data transfer method of this preferred embodiment, since a dummy response message is returned within the storage system on the transmitting side and data packets are sequentially transmitted, even when the delay time increases, transfer speed does not decrease and can be kept almost constant.

As described so far, in the data transfer method according to this preferred embodiment, the same erasure correction coding is adopted as both an encoding method for storing data in a disk device and an encoding method for reading data from a disk device and for transferring the data to another storage system. Therefore, when data is transferred to another storage system in mirroring and the like, the data read from the disk device can be directly transmitted to a network. Therefore, the conventional process of encoding data by an encoding method for data transfer after decoding it is not required, thereby improving data transfer efficiency.

When a data loss, such as a packet loss or the like is detected on a network, parity data is encoded and is additionally transmitted to a data transfer destination storage system. Since data is not re-transmitted, the amount of data to be transmitted never increases according to the increase of a loss factor even when a data loss factor increases. Thus, even when a loss factor is large, data transfer efficiency can be effectively prevented from decreasing.

Furthermore, according to a storage controller of a preferred embodiment, the same erasure correction coding is used in both an encoding method for storing data in a disk device and an encoding method for transferring data to another storage system. In this case, when data stored in a disk device is transferred to another storage system, it is unnecessary to encode by an encoding method for transfer after encoded data read from a disk device is decoded once. Thus, the efficiency of data transmission can be improved.

In addition, when a data loss such as a packet loss occurs on a network, parity data is encoded and is additionally transmitted to another storage system. The amount of parity data to be additionally transmitted is appropriately set according to the data loss factor reported from another storage system side. Since parity data is transmitted without re-transmitting data, even if a data loss factor increases, the amount of data to be transmitted in proportion to this never increases and data transfer efficiency is effectively prevented from decreasing.

A preferred embodiment of the present invention is not limited to the above-described storage devices. A preferred embodiment of the present invention also includes a method for controlling storage executed in the above-described storage controller, a recording medium storing a program for enabling a computer the method and a storage system provided with the above-described storage controller.

According to a preferred embodiment of the present invention, the overhead of a storage system, in the case where data is read from a disk device and is transferred to another storage system can also be reduced by using the same erasure correction coding is used in both an encoding method for storing data in a disk device and an encoding method for transferring data to another storage system, thereby improving the efficiency of data transfer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention have been described in detail, it should be understood that the various changes, substitutions, and alterations could be made hereto without departing from the spirit and scope of the invention.

What is claimed is:

1. A storage controller for controlling to store data in a plurality of disk devices in a storage system provided with the plurality of disk devices, the controller comprising:
an encoding unit for encoding data to be stored in the plurality of disk devices by erasure correction coding to obtain encoded data;
a storage unit for storing the encoded data in the plurality of disk devices and fetching the encoded data from the plurality of disk devices, according to instructions from a host computer; and
a transmitting unit for transmitting the encoded data fetched from the plurality of disk devices by the storage unit to another storage system connected to the storage system via a network.

2. The storage controller according to claim 1, further comprising
a receiving unit for receiving information about a data loss factor on the network, of data addressed to the other storage system, which is transmitted from the other storage system, wherein
the encoding unit generates new parity data of data transmitted from the transmitting unit on the basis of information about the data loss factor, and
the transmitting unit transmits the parity data to the other storage system.

3. The storage controller according to claim 1, further comprising
a dummy response unit for issuing a dummy response of transmission of the data when data addressed to the other storage system is transmitted to the network by the transmitting unit, wherein
when recognizing that a dummy response is issued by the dummy response unit, the transmitting unit transmits subsequent data to be transmitted.

4. The storage controller according to claim 2, further comprising
a dummy response unit for issuing a dummy response of transmission of the data when data addressed to the other storage system is transmitted to the network by the transmitting unit, wherein
when recognizing that a dummy response is issued by the dummy response unit, the transmitting unit transmits subsequent data to be transmitted.

5. The storage controller according to claim 2, wherein
the encoding unit generates the new parity data by calculating respective exclusive OR of a data string including data to be transmitting to the other storage system and a row determined according to a loss factor of the data of an encoding matrix.

6. The storage controller according to claim 5, wherein
the encoding matrix is calculated on the basis of simulation of data transfer between the storage system and the other storage system and is stored by a storage device.

7. The storage controller according to claim 5, wherein
the encoding unit encodes data with timing the new parity data is generated, using the encoding matrix generated using random numbers.

8. The storage controller according to claim 2, wherein
when a data loss is recognized on the basis of information about the data loss factor, the encoding unit calculates a new transmitting code from a code polynomial of Reed-Solomon coding or Cauchy Reed-Solomon coding, and
the transmitting unit transmits the new calculated transmitting code to the other storage system.

9. A storage controller for controlling to store data in a plurality of disk devices in a storage system provided with the plurality of disk devices, the controller comprising:
a receiving unit for receiving encoded data transmitted from another storage system via a network;
a reproduction unit for reproducing data from encoded data received by the receiving unit;
an encoding unit for encoding data by erasure correction coding used to transmit data via the network when the data could be reproduced by the reproduction unit, and
a storage unit for storing encoded data obtained by an encoding process of the encoding unit in the plurality of disk devices.

10. The storage controller according to claim 9, further comprising
a measurement unit for measuring a data loss factor on the network by calculating a ratio of the number of encoded data received by the receiving unit to the number of encoded data transmitted from the other storage system; and
a transmitting unit for transmitting information about the measured loss factor to the other storage system, wherein
the measurement unit calculates the data loss factor by counting the number of encoded data received by the receiving unit using data identification information attached to encoded data transmitted from the other storage system.

11. The storage controller according to claim 9, wherein
when receiving parity data generated by calculating respective exclusive OR of a data string including data transmitted from the other storage system and a row determined according to a loss factor of the data of an encoding matrix, the reproduction unit reproduces data by calculating respective exclusive OR of a data string composed of the parity data and a row determined according to a loss factor of the data of the encoding matrix.

12. An integrated storage system composed of a first storage system and a second storage system connected to the first storage system via a network, the system comprising:
a first encoding unit for encoding data to be stored in a plurality of disk devices provided for the first storage system by erasure correction coding to obtain encoded data;
a storage unit for storing the encoded data in the plurality of disk devices provided for the first storage system and fetching the encoded data from the plurality of disk devices provided for the first storage system, according to instructions from a host computer;
a transmitting unit for transmitting the encoded data fetched from the plurality of disk devices provided for the first storage system by the first storage unit to the second storage system;
a receiving unit for receiving encoded data transmitted from the first storage system via a network;
a reproduction unit for reproducing data from encoded data received by the receiving unit;
a second encoding unit for encoding the data by erasure correction coding used for transfer via the network when the data could be reproduced by the reproduction unit; and
a second storage unit for storing encoded data obtained by an encoding process of the encoding unit in a plurality of disk devices provided for the second storage system.

13. A storage control method for controlling to store data in a plurality of disk devices in a storage system provided with the plurality of disk devices, the method comprising:
encoding data to be stored in the plurality of disk devices by erasure correction coding to obtain encoded data;
storing the encoded data in the plurality of disk devices and fetching the encoded data from the plurality of disk devices, according to instructions from a host computer; and
transmitting the encoded data fetched from the plurality of disk devices to another storage system connected to the storage system via a network.

14. A recording medium storing a storage control program for enabling a computer to control to store data in a plurality of disk devices in a storage system provided with the plurality of disk devices, the program comprising:
encoding data to be stored in the plurality of disk devices by erasure correction coding to obtain encoded data;
storing the encoded data in the plurality of disk devices and fetching the encoded data from the plurality of disk devices, according to instructions from a host computer; and
transmitting the encoded data fetched from the plurality of disk devices to another storage system connected to the storage system via a network.
